(19) United States
(12) Patent Application Publication
(10) Pub. No.: US 2018/0286972 A1
(43) Pub. Date: Oct. 4, 2018

(54) Aluminum-rich field-plated nitride transistors for record high currents

(71) Applicant: Ahmad Tarakji, Sacramento, CA (US)

(72) Inventor: Ahmad Tarakji, Sacramento, CA (US)

(21) Appl. No.: 15/530,643

(22) Filed: Feb. 13, 2017

(51) Int. Cl. H01L 29/778; H01L 29/20; H01L 21/02; H01L 29/66

(52) U.S. Cl. CPC H01L 29/7787; H01L 29/2003; H01L 29/66462; H01L 21/0262; H01L 21/02636; H01L 21/0254

(57) ABSTRACT

New Nitride semiconductor epitaxy incorporating high Aluminum content is presented. It incorporated traces of Indium that adequately tuned its lattice size closer to that of a narrower bandgap semiconductor that interfaced it and formed a 2DEG device channel QW. The incorporation of adequate low molar fraction of Indium into AlN compound that possesses strong Spontaneous-Polarization enabled the lattice size of this epitaxy to better match that of the semiconductor interfacing it and did consequently grow thicker and induced very high carrier-concentrations into the device 2DEG QW resulting therefore in highest current densities.

### BACKGROUND OF THE INVENTION

Since Enhancement-mode AlInN/GaN High-Electron-Mobility-Transistors (HEMTs) are known to produce lower currents compared to Depletion-mode AlInN/GaN HEMTs that have same device peripheries, future high power radio-frequency amplifiers can better profit from the higher current densities of the Depletion-mode AlInN/GaN devices. This is especially true given that both Enhancement- and depletion-mode AlInN/GaN devices require Integrated-Circuit to drive them (IC drivers). It was already demonstrated that such Depletion-mode Nitride devices can effectively and efficiently operate in “Normally off” mode with custom-built IC drivers that can be specifically designed to suppress or reduce the power losses in them. One example IC driver for such Depletion-mode Nitride based devices was reported by: Bo Wang et al., “An Efficient High-Frequency Drive Circuit for GaN Power HFETs”, IEEE trans. Indust. Appl., vol. 45, no. 2, 2009.

Among the many published works that reported on the lower current densities from Enhancement-mode AlInN/GaN HEMTs are those of: Sarosji et al., “High performance AlInN/AlN/GaN p-GaN back barrier Gate-Recessed Enhancement-mode HEMT”, Supperlattices and Microstructures, vol. 75, 2014; and, Ronghua Wang et al., “Gate-Recessed Enhanced-Mode InAlN/GaN HEMTs with 1.9 A/mm Drain Current Density and 800 mS/mm Transconductance”, IEEE Elec. Dev. Lett., vol. 31, no. 12, 2010.

Depletion-mode transistors based on novel AlInN/GaN heterojunctions are known to embrace strong Spontaneous-Polarizations and consequent higher 2DEG carrier-concentrations. They typically produce 2DEG carrier-concentrations in the range of: 2.0×10¹³ cm⁻²-2.45×10¹³ cm⁻², and GaN 2DEG Mobility's between 1220 cm²/(V·s) and 1320 cm²/(V·s). Their carrier-concentrations are substantially higher than what is typically obtained today from the more conventional AlGaN/GaN HEMTs. Their GaN 2DEG Mobility's are also higher due to their same higher carrier-concentrations that more efficiently screen-out the defects density in their GaN 2DEG. Both, high 2DEG carrier-concentration and high Mobility are required to achieve high current-densities and high Transconductance. Similarly, both high Transconductance and high current-densities are required to deliver superior radio-frequency output powers. Among the many works reporting on these very high 2DEG carrier-concentrations from AlInN/GaN HEMTs are those of: Stefano Tirelli at al., “AlN-capped AlInN/GaN High Electron Mobility Transistors with 4.5 W/mm output Power at 40 GHz, Jap. Journl. Appl. Phys., vol. 52, 2013; and, Zhang Xue-Feng et al., “Electrical characteristics of AlInN/GaN HEMTs under cryogenic operation”, Chin. Phys. B, vol. 22, no. 1, 2013. These very high 2DEG carrier-concentrations from AlInN/GaN HEMTs are mainly attributed to the high Aluminum-content in their AlInN-barrier that places this alloy closer to AlN. AlN possesses the strongest Spontaneous-Polarization among all the Nitride compounds and has a Curie temperature well above 1000° C. This is what gives it its high chemical/thermal stability. In comparison, GaN decomposes in atmosphere around 650° C. These benchmarks for AlN were well described by: F. Medjdoub et al., “Status of the Emerging InAlN/GaN Power HEMT Technology”, The Open electrical and Electronic Engineering Journal, 2, 2008.

Results from a device incorporating an all AlN-barrier (AlN/GaN HEMT) reported on an even higher 2DEG carrier-concentration of 2.75×10¹³ cm⁻²: Tom Zimmermann et al., “AlN/GaN Insulated-Gate HEMTs with 2.3 A/mm Output Current and 480 mS/mm Transconductance”, IEEE Elec. Dev. Lett., vol. 29, no. 7, 2008. This highest carrier-concentration was achieved thanks to the very strong Spontaneous-Polarization of AlN. This reported carrier-concentration is an order of magnitude higher than what is best attained today from the more conventional AlGaN/GaN-type HEMTs. A corresponding 2DEG Mobility of 1367 cm²/(V·s) was also reported from this device having an AlN-barrier 3.5 nm thick. Drawback from this AlN/GaN HEMT however was that its AlN-barrier (or AlN epitaxy) grew excessively strained that only lower potentials can be applied to its Drain so that it can operate reliably. The device from that specific work by Zimmermann et al. showed clear signs of distorted Current-Voltage (IV) characteristics at applied Drain potentials as low as 4V-8V in both DC and Pulsed bias. (This is in comparison to the much more stable I-V characteristics of the AlInN/GaN HEMTs from the works of Stefano Tirelli et al.; and Zhang Xue-Feng et al. that showed stable performance at Drain potentials as high as 12-15V).

Both, thick and extra Aluminum-rich epitaxial barriers are required to achieve strongest Spontaneous-Polarization and a consequent highest carrier-concentration in GaN 2DEG. The constraining challenge to this goal arises from the fact that higher Aluminum content does tensile-strain these epitaxies, impeding therefore their thicker growth. This tensile strain can also cause reduced overall device performance, less reliability and reduced lifetime due to lattice relaxation. Precision structural optimization of the epitaxy is therefore key to balance the high Aluminum content to the maximum attainable thickness of the AlInN in these AlInN/GaN HEMT devices.

### BRIEF SUMMARY OF THE INVENTION

Our new and unique approach to designing AlInN/GaN HEMTs having highest 2DEG carrier-concentrations and current-densities utilizes Migration-Enhanced-Metal-Organic-Chemical-Vapor-Deposition (MEMOCVD) to incorporate into the device epitaxial barrier adequate compositions of InN and AlN to alleviate or adequately suppress the tensile-strain to the GaN that lies underneath it prior to growing an added AlN layer on top of AlInN. This consequently allows growth of thicker Aluminum-rich barrier (epitaxy) which consequently yields stronger Spontaneous-Polarization into the device GaN 2DEG. The added AlN epitaxy on top of AlInN may incorporate smaller traces of indium as it can be practically impossible to grow a perfectly pure top AlN layer. This top AlN layer is grown with Pulsed-Atomic-Layer-Epitaxy (PALE) and it substantially further boosts the Spontaneous-Polarization and increases carrier-concentration in the device GaN 2DEG. It also proved to enhance surface-Breakdown. An optional ultra-thin (^{˜}0.5-3 nm) AlN-spacer may also be sandwiched between the GaN and the AlInN layers; its purpose is to alleviate the interface roughness scattering in the 2DEG QW and provide added boost to the Spontaneous-Polarization.

Not any prior art utilized such thicker Aluminum-rich epitaxial barrier made of AlN on top of thick AlInN epitaxy (>3-3.5 nm) to maximize Spontaneous-Polarization and increase the 2DEG carrier-concentration in a GaN 2DEG while still maintaining a high device channel Mobility. The first report ever on this new epitaxial design came in 2010 from the inventor and the author of this patent himself; Q. Fareed and A. Tarakji, “High voltage operation of field-plated AlInN HEMTs”, Phys. Status Solidi C8, no 7-8, 2011. No further progress was made since. Record high 2DEG carrier-concentrations were obtained then with 2.75×10¹³ cm⁻² for a 9 nm thick AlInN incorporating 17-21% Indium and a 1.5 nm AlN top layer. Stefano Tirelli et al., attempted to duplicate in 2013 this same epitaxial design but failed to achieve the thick AlInN that provides stronger Spontaneous-Polarization and higher GaN 2DEG carrier concentration. He (apparently) failed to incorporate enough traces of Indium to sufficiently alleviate the lattice mismatch to GaN (he consequently achieved a thickness for his AlInN epitaxy that was only 3.5 nm; that is same thickness as the AlN-barrier in the device structure that was reported by Tom Zimmermann et al.). As a result he obtained a low GaN 2DEG carrier-concentration (2×10¹³ cm⁻²). The work by Shiping Guo et al., “AlInN HEMT grown on SiC by metalorganic vapor phase epitaxy for millimeter-wave applications”, Phys. Status Solidi A 207, No. 6, 2010, did not employ on the other hand the AlN epitaxy on top of AlInN that substantially boosts the Spontaneous-Polarization and he consequently obtained an even lower 2DEG carrier-concentration of 1.71×10¹³ cm⁻² even while using a thicker AlInN that is close to 10 nm thick.

Since some native lattice-mismatch always exists between AlInN and GaN even when optimum Indium is incorporated to suppress lattice mismatch (lattices of different epitaxial layers can never be perfectly matched to an exact precision and a degree of native lattice-mismatch always exists), an intrinsic strain in AlInN epitaxy tends to always develop as this epitaxy thickens. Because this strain increases further due to high applied fields between the device Gate and its GaN 2DEG channel (due to piezoelectric induced-strain), the HEMTs incorporating this thick and strained AlInN epitaxy can profit from the incorporation of Field-Plated Gate designs that lessen the effect from these high fields. This piezoelectric induced-strain was described in the works of: Grigory Simin et al., “Induced Strain Mechanism of Current Collapse in AlGaN/GaN heterostructure Field-Effect Transistors”, Appl. Phys. Lett., vol. 79, no. 16, 2001; and, J. H. Leach et al., “Effect of lattice mismatch on gate lag in high quality InAlN/AlN/GaN HFET structures”, Phys. Status Solidi A. 2009.

Since this invention comprises in its entirety a new unique epitaxial structure for Aluminum-rich epitaxial barriers (made of either AlN/AlInN or AlN/AlInN/AlN-spacer) that induce strongest Spontaneous-Polarizations into a device 2DEG QW it extends to any and all narrower bandgap semiconductors that may be incorporated instead of GaN to interface these barriers and form a 2DEG QW; it similarly extends to any and all Enhancement-mode devices that employ this same Aluminum-rich Nitride epitaxy for no purpose other than to increase 2DEG carrier-concentration in their 2DEG QW.

### BRIEF DESCRIPTION OF THE SEVERAL VIEWS OF THE DRAWINGS

FIG. 1: Schematic illustrating the variations of Spontaneous-polarization and a-Lattice size with the molar fraction compositions of InN, AlN, and GaN. It specifically shows the relatively lower rate of change in Spontaneous-Polarization with changes of the fraction compositions of Indium (or Indium-Nitride) in AlN (as compared to the fraction compositions of GaN in AlN). It also shows the corresponding scaling of the a-lattice with these same changes.

FIG. 2: Epitaxial layering of a fabricated Schottky-type Gate AlN/AlInN/AlN-spacer/GaN HEMT and a corresponding cartoon drawing illustrating its a-lattice stacking. The growth of thicker AlInN still increases strain in the AlInN even when optimum Indium composition (^{˜}17-21%) is incorporated to best lattice-match the AlInN to GaN. Although the figure shows thicker AlInN than the AlN on top of it, the thickness of both layers can or may vary.

(AlN-spacer may be omitted, and a narrower bandgap semiconductor other than GaN may always be utilized instead to interface this Aluminum-rich barrier).

FIG. 3: Same AlN/AlInN/AlN-spacer HEMT as that of FIG. 2 can be fabricated with thick Nano-Crystal-Diamond (NCD) film as substitute to a bulk substrate. For this process, the bulk substrate and its AlN nucleation film are first etched after the full growth of all the epitaxies on the bulk substrate and the device fabrication. A thin dielectric film is then deposited onto the exposed GaN buffer. This is followed with the deposition of thick NCD film (^{˜}100 μm or higher). This places the GaN 2DEG within 1 μm of this NCD film and results in an excellent thermal conductance between the hot GaN 2DEG and this NCD. (The device structure is shown for ^{˜}17-21% Indium in AlInN). Although the figure shows thicker AlInN than the AlN layer on top of it, the thickness of both layers can vary.

(AlN-spacer may be omitted, and a narrower bandgap semiconductor other than GaN may always be utilized instead to interface this Aluminum-rich barrier).

FIG. 4: Recessed-Gate structures for same AlN/AlInN/AlN-spacer/GaN HEMT having a Schottky-type Gate, and an Insulated-type Gate. The Gate-dielectric can be any dielectric film: SiO₂, Si₃N₄, HfO₂, Al₂O₃, etc . . . (The device structure is shown for ^{˜}7-21% Indium in AlInN). Although the figure shows thicker AlInN than the AlN layer on top of it, the thickness of both layers can vary. Although the figure also shows the Schottky and insulated Gates contacting the AlInN these may also contact either AlN layer instead.

(AlN-spacer may be omitted, and a narrower bandgap semiconductor other than GaN may always be utilized instead to interface this Aluminum-rich barrier).

FIG. 5: Field-Plated Gates for same AlN/AlInN/AlN-spacer/GaN HEMT with a Schottky-type Gate, and with an Insulated-type Gate. Gate-dielectric can be any dielectric film: SiO₂, Si₃N₄, HfO₂, Al₂O₃, etc. . . . . The Gate-to-Drain spacing (LGD) can be optionally larger than the Gate-to-Source spacing (LGS). (The device structure is shown for an AlInN incorporating ^{˜}17-21% indium). Although the figure shows thicker AlInN than the AlN layer on top of it, the thickness of both layers can vary.

(AlN-spacer may be omitted, and a narrower bandgap semiconductor other than GaN may always be utilized instead to interface this Aluminum-rich barrier).

FIG. 6: Current-Voltage (I-V) characteristics of the fabricated Depletion-mode AlN/AlInN/AlN-spacer/GaN HEMT embodying this new and thick Aluminum-rich AlN/AlInN/AlN-spacer epitaxy on a Silicon-Carbide (SiC) substrate. The device incorporated an AlInN thickness of 9 nm with ^{˜}17-21% Indium and a top AlN layer thickness of 1.5 nm. An excellent corresponding current-density of 2 A/mm was obtained given the long device Gate-length of 1.5 μm and the very large magnitude for LGD (6 μm). This current-density can be expected to be higher for shorter Gate-length devices having LGD values closer to 1-1.5 μm.

FIG. 7: Summary-table showing the measured scaling of the carrier-concentration and 2DEG Mobility with the increasing thickness of AlInN (^{˜}17-21% Indium was incorporated—That is the optimum composition for a best lattice-match to GaN). Apparently, for an AlInN 12 nm thick, it was difficult to maintain sufficient strain suppression and the 2DEG GaN-channel Mobility started degrading. The thickness of the top AlN layer was 1.5 nm.

### DETAILED DESCRIPTION OF THE INVENTION

Our new approach to designing new Aluminum-rich barriers for HEMT devices that have strongest Spontaneous-Polarization and highest current-densities grows via Migration-Enhanced-Metal-Organic-Chemical-Vapor-Deposition (MEMOCVD) traces of Indium into AlN prior to growing an all AlN layer on top of it. This enables growth of thicker barrier that induces stronger Spontaneous-polarization into the devices 2DEG QW. Because the incorporation of Indium into an AlN epitaxy scales or modulate the corresponding lattice size proportionally with little or least effect on reducing Spontaneous-Polarization a closer lattice-match to the narrower bandgap semiconductor that is below the device barrier can be attained and this is what enables an adequate tuning for a thicker device barrier that induces strongest Spontaneous-polarization into the device 2DEG QW and all while maintaining a high Mobility in same device 2DEG QW channel. Both thicker barrier and higher Aluminum content in barrier increase Spontaneous-Polarization and carrier-concentration in 2DEG QW.

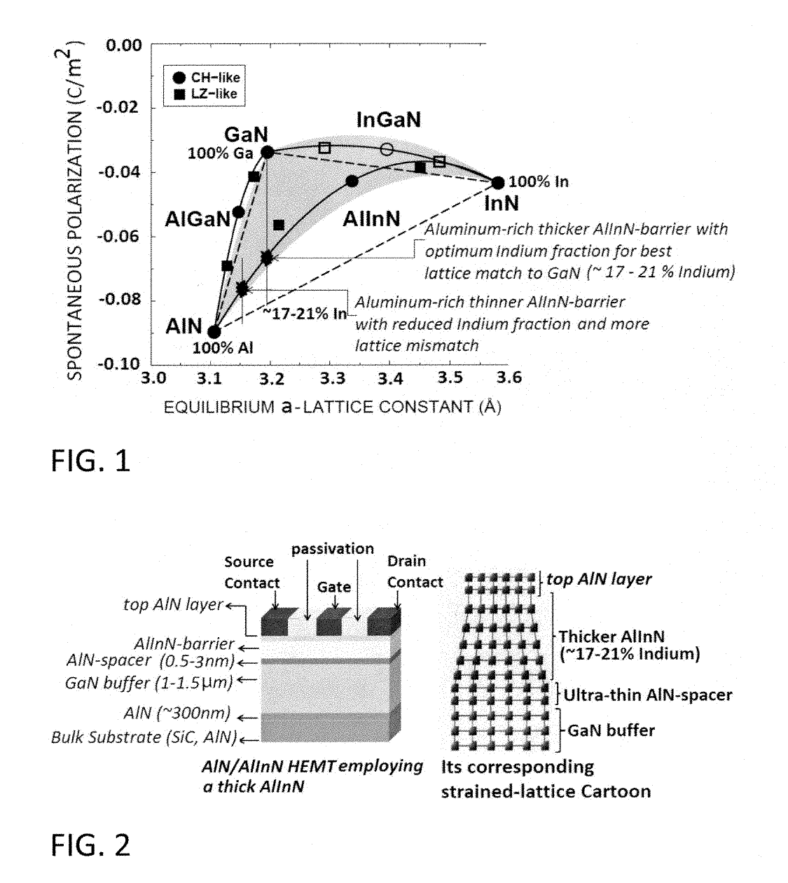

The typical molar fractions for Indium in a HEMT device barrier that can achieve best lattice-match to a GaN semiconductor below it are anywhere close to 17% and 21%, but less Indium with more Aluminum content may still concede higher Spontaneous-Polarization even when this barrier grows less thick and this is due to the inherent strongest Spontaneous-Polarization of AlN. A fine tuning or the optimization of the Indium composition in the HEMT device barrier to optimize best tradeoff between this barrier thickness and its Aluminum composition is therefore key to achieving highest Spontaneous-polarization and a best device performance. Furthermore it is important that the barrier does not grow excessively strained to impact the GaN 2DEG that it interfaces as this may degrade or reduce its Mobility; this makes the incorporation of Indium into AlN in a HEMT device barrier as crucial for a good 2DEG channel Mobility as for a highest 2DEG carrier-concentration. The scaling of this AlInN lattice and of its corresponding Spontaneous-Polarization through varying the molar composition of Indium is depicted in the schematic of FIG. 1.

As the FIG. 1 shows a strong Spontaneous-Polarization can either be attained by incorporating less Aluminum (with ^{˜}17%-21% Indium) which enables growth of a relatively thick AlInN (^{˜}6 nm-12 nm) due to best lattice match to the GaN semiconductor that is below AlInN, or it can be attained by increasing the Aluminum content which causes this AlInN to grow less thick while still inducing a strong Spontaneous-Polarization into a device 2DEG QW due to the inherent strong Spontaneous-Polarization of AlN.

The 17-21% range for the required optimum molar composition of Indium in AlInN to achieve closest lattice-match to GaN is simply due to the typical natural variations of crystallographic imperfections in the epitaxies (e. g. defects density) that can vary naturally between reactor-to-reactor and run-to-run.

Because of the intrinsic residual lattice-mismatch between the AlInN and the GaN buffer that lies beneath it, this AlInN does naturally strain more as it grows thicker and may consequently further increase the Spontaneous-Polarization and the 2DEG carrier-concentration; this is because both: The total thickness of AlInN, and its tensile-strain do increase the Spontaneous-Polarization and the corresponding 2DEG carrier-concentration (F. Medjdoub et al.). After tuning or adequately optimizing the thickness of the AlInN epitaxy an AlN layer is then grown on top of this AlInN through Pulsed-Atomic-Epitaxy (PALE) so to further boost the net Spontaneous-Polarization into the device 2DEG QW. This AlN also enhances the surface-Breakdown in the corresponding HEMT device structure. The thicknesses of both the AlInN epitaxy and the AlN layer on top of it are best optimized to induce the strongest possible Spontaneous-polarization into the device 2DEG QW and all while maintaining a high Mobility in it.

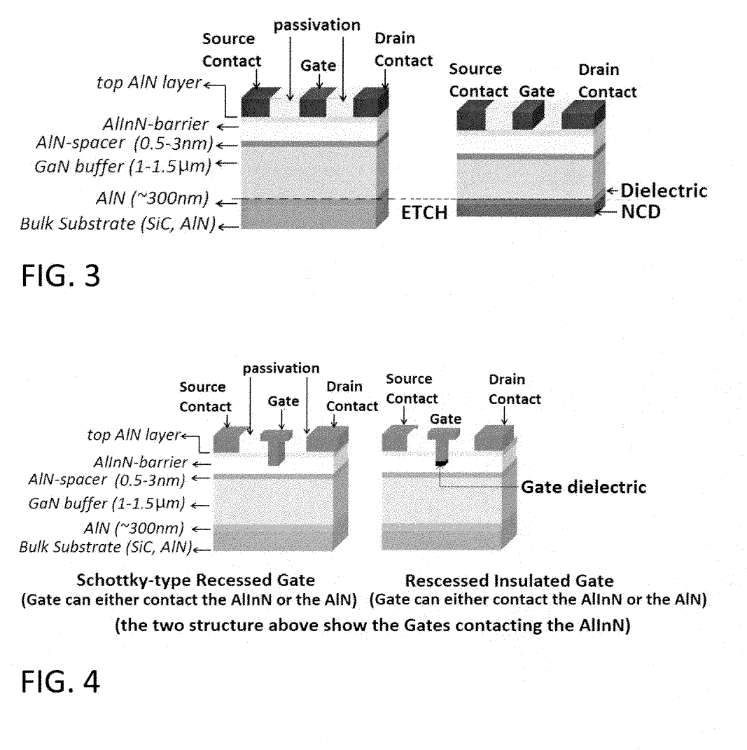

All epitaxial layers for a HEMT device having an Aluminum-rich Nitride barrier can be grown using standard precursors on either an insulating bulk Silicon-Carbide (SiC) substrate or on a bulk Aluminum-Nitride (AlN) substrate (a bulk AlN substrate can result in reduced defects density in the epitaxial growth of AlInN due to its better lattice-match to GaN). A 100\acute{Å}-250\acute{Å} low temperature AlN buffer is deposited first atop the substrate. Then temperature is raised to 1080° C. to grow close to 0.31 μm thick AlN layer with Pulsed-Atomic-Layer-Epitaxy (PALE). Growth of approximately 1.5 μm thick semi-insulating GaN is then carried, followed by an AlN-spacer (this spacer may be optional). The typical thickness of this AlN-spacer is between 0.5 nm and 3 nm. This is then followed by growth of the AlInN and the AlN layer on top of it. A typical epitaxial layering for a HEMT device that incorporates this Aluminum-rich Nitride barrier is shown in FIG. 2. The particular device structure in that figure shows a device structure incorporating the relatively thick AlInN barrier (>3-3.5 nm) with the AlN layer on top of it. Note that although the top AlN layer of FIG. 2 is shown thinner than the AlInN, the thickness of both AlInN and the AlN on top can vary to tune for strongest possible Spontaneous-Polarization. Same device structure of FIG. 2 may also incorporate an Insulated Gate dielectric. Though either Silicon-Carbide (SiC) or Aluminum-Nitride (AlN) can be used as bulk substrates other films such as: Nano-Crystalline-Diamonds (NCD's) or other highly thermal conductive bulk substrates such as bulk crystal Diamond may also be used. For an NCD substrate process, the initial bulk substrate of a fabricated device and the AlN nucleation film are first etched after all the phases of the epitaxial growths, passivation, and metallization are completed to fabricate or form the device on bulk SiC or AlN. A thin dielectric film is then deposited onto the exposed GaN buffer. This is then followed with deposition of a thick NCD film that is close to 100 μm thick. This enables the hot GaN-channel of the device to be brought within 1 μm of this NCD, resulting therefore in a superior thermal management. A cartoon drawing depicting this HEMT device on NCD is shown in FIG. 3. An added Field-Plated Gate design can weaken the electric-field around the device Gate edge and lessen the induced straining mechanism that is due to the inverse-piezoelectric effect enabling therefore the application of higher biases to these devices. The Field-Plates can incorporate optional wider Gate-to-Drain spacing (LGD) compared to the Gate-to-Source spacing (LGS)

HEMT devices incorporating such Aluminum-rich Nitride epitaxies include Enhancement-mode devices and can embody any Gate structures as this patent pertains to no other than the AlN/AlInN or AlN/AlInN/AlN-spacer epitaxies that induce strongest Spontaneous-Polarization into a device 2DEG QW. These include: Schottky and insulated submicron-length Gates with and without Field-Plates, Schottky and insulated multi-legged and single-legged large-periphery Gates with and without Field-Plates, Schottky and insulated recessed Gates with and without Field-Plates, and Schottky and insulated submicron-length recessed Gates with and without Field-Planes, etc. . . .

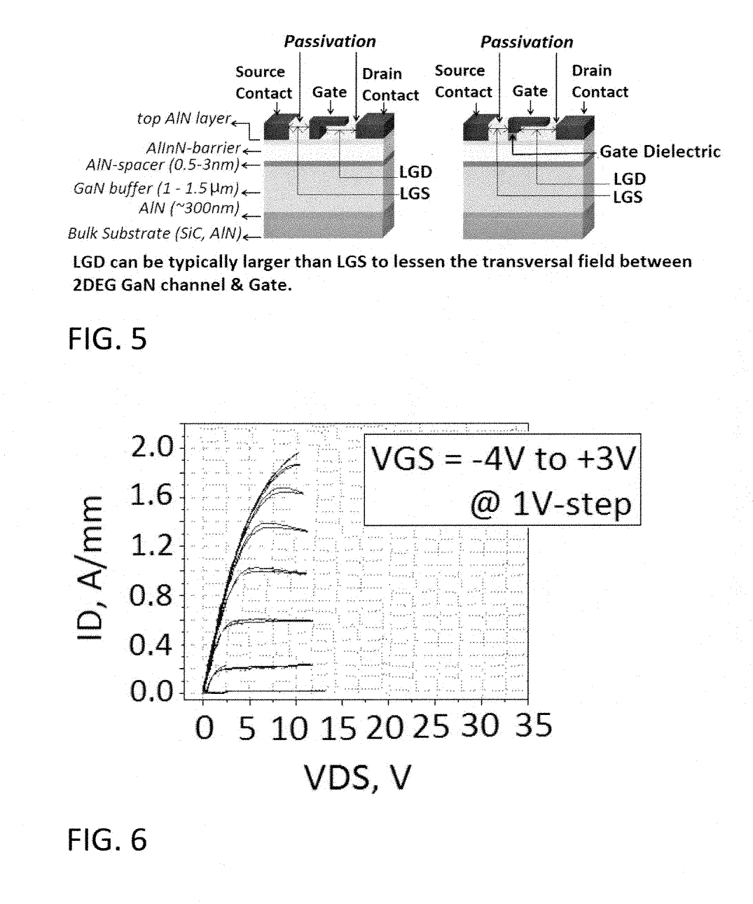

FIG. 4 shows cartoon drawings of transistor device structures symbolizing the embodiment of a Schottky-type recessed Gate and a recessed Insulated Gate. Though the FIG. 4 shows both recessed Gates contacting the AlInN layers, these recessed Gates may also contact the AlN on top or the AlN-spacer instead. FIG. 5 shows side-by-side cartoon drawings of Field-Plated Gate designs for a Schottky-type Gate and for an Insulated Gate that incorporate thin dielectric film between the semiconductor epitaxy and the Gate. The Field-Plated Gates of FIG. 5 can also be recessed.

Fabrications of devices incorporating this relatively thick Aluminum-rich multi-layered epitaxy consisting of either an AlN/AlInN or an AlN/AlInN/AlN-spacer follow the known standard steps for device/process fabrication that do terminate with an adequate surface treatment (using Si₃N₄, Benzo-Cyclo-Butane, Al₂O₃, etc. . . . for passivation). High quality surface-passivation is critical given the high reactivity of the Aluminum in the AlN layer on top of AlInN with the Oxygen in atmosphere.

FIG. 6 shows the measured DC I-V characteristics on a fabricated Depletion-mode AlN/AlInN/AlN-spacer/GaN HEMT having an AlInN 9 nm thick and a top AlN layer about 1.5 nm thick (the AlInN incorporated close to 17%-21% Indium). It also included an AlN-spacer between the GaN buffer and the AlInN that is about 0.5-3 nm. Measurements were taken with a 60 Hz-Tektronix-Curve-Tracer. Excellent stability of these I-V curves were confirmed up to a 15V bias sweep to the Drain and during prolonged operations (>10 hours).

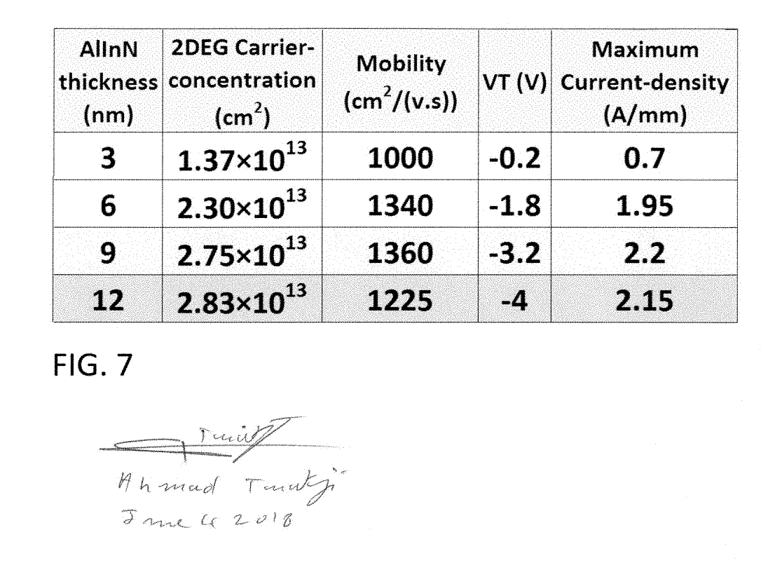

FIG. 7 shows a summary-Table depicting the scaling of the carrier-concentration and the corresponding increase of 2DEG Mobility with thicker AlInN. Apparently, as the AlInN grew thicker higher 2DEG carrier-concentrations resulted. These also increased the 2DEG channel Mobility due to a more effective screen-out of crystallographic defects in GaN. However, as AlInN grew 12 nm thick the strain in the barrier became apparently pronounced enough to impact the GaN region interfacing this barrier and the 2DEG GaN channel Mobility started degrading or reducing as a result. All the devices in this summary incorporated close to 17%-21% Indium in their AlInN.

What is claimed is:

1. A multi-layered Aluminum-rich Nitride epitaxy:
An Aluminum-rich Nitride epitaxy atop a narrower bandgap semiconductor interfacing it to achieve a strongest Spontaneous-Polarization into a Two-Dimensional-Electron-Gas (2DEG) Quantum-Well (QW); this Aluminum-rich Nitride epitaxy consists of a layer of Aluminum-Nitride (AlN) atop a layer of Aluminum-Indium-Nitride (AlInN), an added layer of AlN (AlN-spacer) may also be included below the AlInN; purpose of the AlInN is to alleviate the strain to the underlying narrower bandgap semiconductor which lattice size is inherently mismatched to that of AlN; this permits growth of thicker Aluminum-rich Nitride epitaxy atop the 2DEG QW which consequently increases the Spontaneous-Polarization and 2DEG carrier concentration in a device 2DEG QW; both high Aluminum content and thicker Aluminum-rich Nitride epitaxy increase Spontaneous-Polarization and boost 2DEG carrier concentration in a device 2DEG QW channel; the AlN-spacer below the AlInN can lessen the interface roughness scattering in the device 2DEG QW and can contribute to an even higher Spontaneous-Polarization and 2DEG carrier concentration; the Indium molar fraction in AlInN dictates the thickness of this Aluminum-rich Nitride epitaxy; it can either grow thick and more lattice matched to the semiconductor below it through incorporation of optimum Indium composition, or it can grow less thick and more strained with more Aluminum and less Indium contents; both epitaxial designs can ensure a strong Spontaneous-Polarization and a 2DEG carrier concentration that can reach or exceed 3×10¹³ cm⁻²;
this claim extends to any and all Aluminum-rich Nitride barriers that may have instead an AlInN epitaxy with a graded Indium composition such that their Indium molar fraction is highest at center and lower or zero at the top (this is because it can be practically impossible to incorporate an all perfectly pure AlN layer on top of AlInN, residual traces of Indium may or can always exist in such AlN layer); this claim extends additionally to any and all device structures that incorporate this Aluminum-rich Nitride epitaxy for purpose of increasing 2DEG carrier concentration in a semiconductor 2DEG QW; this includes: Devices with submicron-Gates, large-periphery devices with multi-legged or single-legged Gates, devices with recessed Gates and devices with insulated Gates that incorporate any type of insulating dielectric between their Gate and the semiconductor; it also extends to any and all device structures that employ same Aluminum-rich Nitride epitaxy atop a portion or portions of the narrower bandgap semiconductor below it for no purpose other than to increase 2DEG carrier-concentration; it similarly extends to any and all Enhancement-mode devices that employ this Aluminum-rich Nitride epitaxy; this includes Enhancement-mode devices that employ this Aluminum-rich Nitride epitaxy atop only a portion or portions of the narrower bandgap semiconductor below it for no purpose other than to increase 2DEG carrier-concentration; it further extends to any and all device structures that add to same Aluminum-rich Nitride epitaxy small amount of atomic impurities that do not serve any purpose other than to profit from the excellent Spontaneous-Polarization property of this innovative Aluminum-rich Nitride epitaxy by diluting it with traces of other elements that do neither increase Spontaneous-Polarization nor improve device performance;

2. A proprietary technique to form or structure an AlN/AlInN epitaxy by growing a high quality AlN with Pulsed-Atomic-Layer-Epitaxy (PALE) after growth of a highest quality AlInN with Migration-Enhanced-Metal-Organic-Chemical-Vapor-Deposition (MEMOCVD); MEMOCVD is an improvement to PALE that achieves a better Mobility of pre-cursor species for better atomic incorporation, especially for depositions of ternary Nitrides, such as: AlInN;

3. A Field-Plated Gate design that associates with any Heterostructure Field-Effect device that incorporates an Aluminum-rich Nitride epitaxy consisting of either an AlN/AlInN epitaxial barrier or an AlN/AlInN/AlN-spacer epitaxial barrier;
because high electric fields can be applied across these barriers the natural inherent strain that exists across them can become further increased or modulated as a result of these high fields; well-engineered Field-Plated Gate designs can redistribute and weaken the electric field around these devices Gate enabling therefore the application of high voltages to their Gate and Drain.
